(19) United States
(12) Patent Application Publication
(10) Pub. No.: US 2024/0228746 A1
(43) Pub. Date: Jul. 11, 2024

(54) COMPOSITION, FILM, OPTICAL FILTER, OPTICAL SENSOR, IMAGE DISPLAY DEVICE, AND STRUCTURAL BODY

(71) Applicant: FUJIFILM Corporation, Tokyo (JP)

(72) Inventors: Hirotaka TAKISHITA, Haibara-gun (JP); Yoshinori TAGUCH, Haibara-gun (JP)

(73) Assignee: FUJIFILM Corporation, Tokyo (JP)

(21) Appl. No.: 18/428,225

(22) Filed: Jan. 31, 2024

Related U.S. Application Data
(63) Continuation of application No. PCT/JP22/30853, filed on Aug. 15, 2022.

(30) Foreign Application Priority Data
Aug. 19, 2021 (JP) 2021-133931

(51) Int. Cl. C08K 5/549; C08K 3/36; G02B 5/20

(52) U.S. Cl. CPC C08K 5/549; C08K 3/36; G02B 5/208

(57) ABSTRACT

Provided are a composition containing inorganic particles, a cyclic siloxane compound, and a silicone-based surfactant other than the cyclic siloxane compound, in which a content of the cyclic siloxane compound is 0.01 to 10 parts by mass with respect to 100 parts by mass of the silicone-based surfactant; a film formed of the composition; an optical filter, an optical sensor, an image display device; and a structural body.

### CROSS-REFERENCE TO RELATED APPLICATIONS

This application is a Continuation of PCT International Application No. PCT/JP2022/030853 filed on Aug. 15, 2022, which claims priority under 35 U.S.C § 119(a) to Japanese Patent Application No. 2021-133931 filed on Aug. 19, 2021. Each of the above application(s) is hereby expressly incorporated by reference, in its entirety, into the present application.

### BACKGROUND OF THE INVENTION

### 1. Field of the Invention

The present invention relates to a composition containing inorganic particles. In addition, the present invention relates to a film, an optical filter, an optical sensor, an image display device, and a structural body.

### 2. Description of the Related Art

An optically functional layer such as a low refractive index film is applied to, for example, a surface of a transparent base material in order to prevent reflection of incident light. Application fields of the optically functional layer are wide, and the optically functional layer is applied to products in various fields such as an optical instrument, a building material, an observation instrument, and a window glass. As a material thereof, various materials, both organic and inorganic, are used and targeted for development. Among these, in recent years, development of materials applied to an optical instrument has been promoted. Specifically, in a display panel, an optical lens, an image sensor, and the like, a search for materials having physical properties and workability, which are suitable for the products, has been promoted.

For example, an optically functional layer applied to a precision optical instrument such as an image sensor is required to have fine and accurate processability. Therefore, in the related art, a vapor phase method such as a vacuum evaporation method and a sputtering method, which is suitable for fine process, has been adopted. As a material, for example, a single-layer film consisting of MgF₂, cryolite, or the like has been put into practical use. In addition, attempts have also been made to apply a metal oxide such as SiO₂, TiO₂, and ZrO₂.

On the other hand, in the vapor phase method such as a vacuum evaporation method and a sputtering method, since processing equipment and the like are expensive, manufacturing cost may be high. Correspondingly, in recent years, it has been studied to manufacture the optically functional layer such as a low refractive index film using a composition containing inorganic particles such as silica particles.

JP2014-034488A discloses that an antireflection film or the like is produced using a composition containing silica particles having a hollow structure.

### SUMMARY OF THE INVENTION

In recent years, there has been a demand for a composition containing inorganic particles, with which a film with more suppressed defects can be formed.

However, in the composition containing inorganic particles such as silica particles, during film formation, defects such as unevenness due to aggregates of the inorganic particles tend to occur on a surface of the film. According to studies of the present inventor, it has been found that there is room for further improvement even in the composition disclosed in JP2014-034488A.

Therefore, an object of the present invention is to provide a composition capable of forming a film with suppressed defects, a film, an optical filter, an optical sensor, an image display device, and a structural body.

The present invention provides the following.

<1> A composition comprising:

inorganic particles;

a cyclic siloxane compound; and

a silicone-based surfactant other than the cyclic siloxane compound,

in which a content of the cyclic siloxane compound is 0.01 to 10 parts by mass with respect to 100 parts by mass of the silicone-based surfactant.

<2> The composition according to <1>,

in which the cyclic siloxane compound is a compound represented by Formula (1),

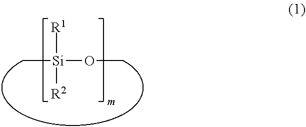

in Formula (1), R¹ and R² each independently represent a hydrogen atom or a substituent, and m represents an integer of 3 to 20.

<3> The composition according to <1> or <2>,

in which the cyclic siloxane compound includes at least one selected from octamethylcyclotetrasiloxane, decamethylcyclopentasiloxane, or dodecamethylcyclohexasiloxane.

<4> A composition comprising:

inorganic particles;

a cyclic siloxane compound; and

a silicone-based surfactant other than the cyclic siloxane compound,

in which the cyclic siloxane compound is at least one selected from octamethylcyclotetrasiloxane, decamethylcyclopentasiloxane, or dodecamethylcyclohexasiloxane, and

a content of the cyclic siloxane compound is 0.01 to 10 parts by mass with respect to 100 parts by mass of the silicone-based surfactant.

<5> The composition according to any one of <1> to <4>,

in which the composition contains two or more kinds of the cyclic siloxane compounds.

<6> The composition according to any one of <1> to <5>,

in which a content of the silicone-based surfactant in the composition is 1 to 2,000 ppm by mass.

<7> The composition according to any one of <1> to <6>,

in which the inorganic particles include silica particles.

<8> The composition according to <7>,

in which the silica particles include at least one selected from silica particles having a shape in which a plurality of spherical silicas are connected in a bead shape, silica particles having a shape in which a plurality of spherical silicas are connected in a planar shape, or silica particles having a hollow structure.

<9> The composition according to any one of <1> to <8>,

in which a content of the inorganic particles in a total solid content of the composition is 20% by mass or more.

<10> A film formed of the composition according to any one of <1> to <9>.

<11> An optical filter comprising:

the film according to <10>.

<12> An optical sensor comprising:

the film according to <10>.

<13> An image display device comprising:

the film according to <10>.

<14> A structural body comprising:

a support;

a partition wall formed of the composition according to any one of <1> to <9>, which is provided on the support; and

a pixel provided in a region partitioned by the partition wall.

According to the present invention, it is possible to provide a composition capable of forming a film with suppressed defects, a film, an optical filter, an optical sensor, an image display device, and a structural body.

### BRIEF DESCRIPTION OF THE DRAWINGS

FIG. 1 is an enlarged view schematically showing silica particles having a shape in which a plurality of spherical silicas are connected in a bead shape.

FIG. 2 is a side-sectional view showing an embodiment of a structural body according to the present invention.

FIG. 3 is a plan view of the structural body as viewed from directly above a support.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by an excimer laser, an extreme ultraviolet ray (EUV light), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, the term “step” denotes not only an individual step but also a step which is not clearly distinguishable from another step as long as an effect expected from the step can be achieved.

### <Composition>

A first aspect of the composition according to the embodiment of the present invention is:

a composition containing inorganic particles, a cyclic siloxane compound and, and a silicone-based surfactant other than the cyclic siloxane compound,

in which a content of the cyclic siloxane compound is 0.01 to 10 parts by mass with respect to 100 parts by mass of the silicone-based surfactant.

In addition, a second aspect of the composition according to the embodiment of the present invention is:

a composition containing inorganic particles, a cyclic siloxane compound and, and a silicone-based surfactant other than the cyclic siloxane compound,

in which the cyclic siloxane compound is at least one selected from octamethylcyclotetrasiloxane, decamethylcyclopentasiloxane, or dodecamethylcyclohexasiloxane, and

a content of the cyclic siloxane compound is 0.01 to 10 parts by mass with respect to 100 parts by mass of the silicone-based surfactant.

With the composition according to the embodiment of the present invention, a film with suppressed defects can be formed. Although the detailed reason why such an effect is obtained is not clear, it is presumed that aggregation due to an interaction between the silicone-based surfactant and the inorganic particles can be suppressed by formulating a predetermined amount of the cyclic siloxane compound.

A viscosity of the composition according to the embodiment of the present invention at 25° C. is preferably 3.6 mPa's or less, more preferably 3.4 mPa's or less, and still more preferably 3.2 mPa's or less. In addition, the lower limit is preferably 1.0 mPa's or more, more preferably 1.4 mPa's or more, and still more preferably 1.8 mPa's or more.

A concentration of solid contents of the composition according to the embodiment of the present invention is preferably 5% by mass or more, more preferably 7% by mass or more, and still more preferably 8% by mass or more. The upper limit is preferably 15% by mass or less, more preferably 12% by mass or less, and still more preferably 10% by mass or less.

The composition according to the embodiment of the present invention can be preferably used as a composition for an optical sensor or an image display device. Specifically, the composition according to the embodiment of the present invention can be preferably used as a composition for forming an optically functional layer in an optical sensor or an image display device. Examples of the optically functional layer include an antireflection layer, a layer of low refractive index, and a waveguide. In addition, the composition according to the embodiment of the present invention can also be used as a composition for forming a partition wall used for separating adjacent pixels in a case of forming pixels on an image area of an optical sensor such as a solid-state imaging element or an image display device. Examples of the pixel include a colored pixel, a transparent pixel, a pixel of a near-infrared transmitting filter layer, and a pixel of a near-infrared cut filter layer. Examples of the colored pixel include a red pixel, a blue pixel, a green pixel, a yellow pixel, a cyan pixel, and a magenta pixel.

Hereinafter, each of the components used in the composition according to the embodiment of the present invention will be described.

### <<Inorganic Particles>>

The composition according to the embodiment of the present invention contains inorganic particles. Examples of the inorganic particles include silica particles, titanium oxide particles, strontium titanate particles, barium titanate particles, zinc oxide particles, magnesium oxide particles, zirconium oxide particles, aluminum oxide particles, barium sulfate particles, aluminum hydroxide particles, calcium silicate particles, aluminum silicate particles, and zinc sulfide particles. Among these, silica particles are preferable due to high affinity with cyclic siloxane.

In addition, a content of the silica particles in the total amount of the inorganic particles contained in the composition according to the embodiment of the present invention is preferably 20% by mass or more, more preferably 50% by mass or more, still more preferably 70% by mass or more, and even more preferably 90% by mass or more. Among these, it is particularly preferable that the inorganic particles are substantially only the silica particles. The case where the inorganic particles are substantially only the silica particles means that the content of the silica particles in the total amount of the inorganic particles is 99% by mass or more, more preferably 99.9% by mass or more, and still more preferably 100% by mass.

Examples of the silica particles include silica particles having a shape in which a plurality of spherical silicas are connected in a bead shape, silica particles having a shape in which a plurality of spherical silicas are connected in a planar shape, silica particles having a hollow structure, and solid silica particles.

As the silica particles, from the reason that it is easy to form a film having a lower refractive index, silica particles having a shape in which a plurality of spherical silicas are connected in a bead shape, silica particles having a shape in which a plurality of spherical silicas are connected in a planar shape, or silica particles having a hollow structure are preferable; and silica particles having a shape in which a plurality of spherical silicas are connected in a bead shape and silica particles having a shape in which a plurality of spherical silicas are connected in a planar shape are more preferable. Hereinafter, the silica particles having a shape in which a plurality of spherical silicas are connected in a bead shape and the silica particles having a shape in which a plurality of spherical silicas are connected in a planar shape are collectively referred to as beaded silica. The silica particles having a shape in which a plurality of spherical silicas are connected in a bead shape may have a shape in which a plurality of spherical silicas are connected in a planar shape.

In addition, in the silica particles, it is also preferable that at least a part of hydroxy groups on surfaces of the silica particles is treated with a hydrophobizing treatment agent which reacts with the hydroxy groups. As the hydrophobizing treatment agent, a compound having a structure which reacts with the hydroxy group on the surface of the silica particles (preferably, a structure which reacts with the hydroxy group on the surface of the silica particles by coupling) so as to improve hydrophobicity of the silica particles is used. The hydrophobizing treatment agent is preferably an organic compound. Specific examples of the hydrophobizing treatment agent include an organosilane compound, an organotitanium compound, an organozirconium compound, and an organoaluminum compound, and from the reason that increase in refractive index can be suppressed, an organosilane compound is more preferable. The silica particles treated with such a hydrophobizing treatment agent are a material corresponding to the inorganic particles, and are a material different from the silicone-based surfactant and the cyclic siloxane compound.

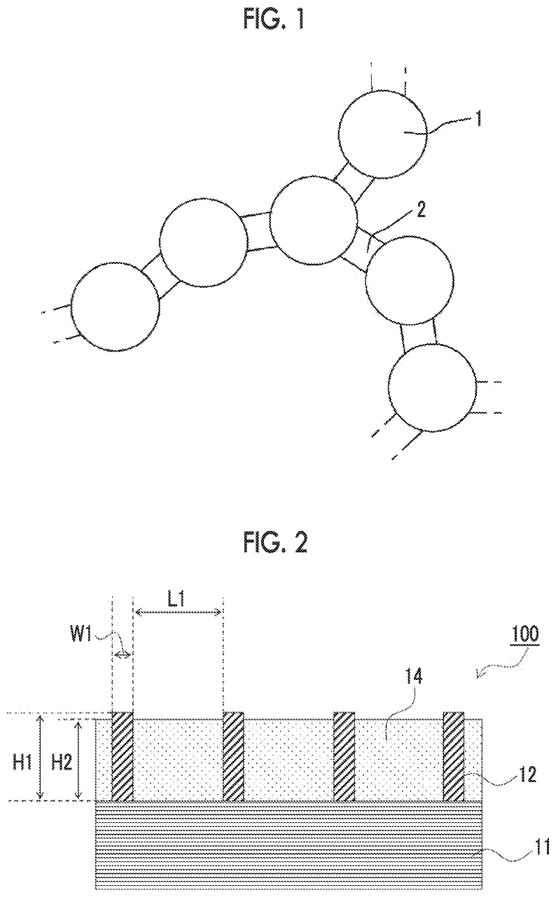

In the present specification, the “spherical” in the “spherical silica” means that the particle may be substantially spherical and may be deformed within a range in which the effect of the present invention is exhibited. For example, the “spherical” is meant to include a shape having roughness on the surface, and a flat surface having a long axis in a predetermined direction. In addition, the “a plurality of spherical silicas are connected in a bead shape” means a structure in which a plurality of spherical silicas are connected to each other in a linear and/or branched form. Examples thereof include a structure in which a plurality of spherical silicas 1 are connected by a connection portion 2 having a smaller outer diameter, as shown in FIG. 1. In addition, in the present invention, the structure in which “a plurality of spherical silicas are connected in a bead shape” includes not only a ring-shaped structure, but also a chain-shaped structure with ends. In addition, the “a plurality of spherical silicas are connected in a planar shape” means a structure in which a plurality of spherical silicas are connected to each other on substantially the same plane. The “substantially the same plane” means not only a case where the plurality of spherical silicas have the same plane, but also a case where the plurality of spherical silicas may be vertically displaced from the same plane. For example, the plurality of spherical silicas may be displaced up and down within a range of 50% or less of a particle diameter of the spherical silica.

In the beaded silica, a ratio D₁/D₂ of an average particle diameter D₁ measured by a dynamic light scattering method and an average particle diameter D₂ obtained by the following expression (1) is preferably 3 or more. The upper limit of D₁/D₂ is not particularly limited, but is preferably 1000 or less, more preferably 800 or less, and still more preferably 500 or less. By setting D₁/D₂ within such a range, good optical characteristics can be exhibited. The value of D₁/D₂ in the beaded silica is also an indicator of a degree of connection of the spherical silica.

$${D}_{2} = 2720 / S \qquad ( 1 )$$

In the expression, D₂ is an average particle diameter of the beaded silica, in units of nm, and S is a specific surface area of the beaded silica measured by a nitrogen adsorption process, in units of m²/g.

The above-described average particle diameter D₂ of the beaded silica can be regarded as an average particle diameter close to a diameter of primary particles of the spherical silica. The average particle diameter D₂ is preferably 1 nm or more, more preferably 3 nm or more, still more preferably 5 nm or more, and particularly preferably 7 nm or more. The upper limit is preferably 100 nm or less, more preferably 80 nm or less, still more preferably 70 nm or less, even more preferably 60 nm or less, and particularly preferably 50 nm or less.

The average particle diameter D₂ can be replaced by a circle-equivalent diameter (DO) in a projection image of the spherical portion measured by a transmission electron microscope (TEM). Unless otherwise specified, the average particle diameter based on the circle-equivalent diameter is evaluated by the number average of 50 or more particles.

The above-described average particle diameter D₁ of the beaded silica can be regarded as a number average particle diameter of secondary particles in which a plurality of spherical silicas are collected. Therefore, a relationship of D₁>D₂ is usually satisfied. The average particle diameter D₁ is preferably 5 nm or more, more preferably 7 nm or more, and particularly preferably 10 nm or more. The upper limit is preferably 100 nm or less, more preferably 70 nm or less, still more preferably 50 nm or less, and particularly preferably 45 nm or less. Unless otherwise specified, the above-described average particle diameter D₁ of the beaded silica is measured using a dynamic light scattering type particle size distribution measuring device (Microtrac UPA-EX150, manufactured by Nikkiso Co., Ltd.). The procedure is as follows. A dispersion liquid of the beaded silica is divided into 20 ml sample bottles, and diluted with propylene glycol monomethyl ether so that the concentration of solid contents is 0.2% by mass. The diluted sample solution is irradiated with 40 kHz ultrasonic waves for 1 minute, and immediately after that, the sample solution is used for test. Data is captured 10 times using a 2 ml quartz cell for measurement at a temperature of 25° C., and the obtained “number average” is regarded as the average particle diameter. For other detailed conditions and the like, the description of “Particle size analysis—Dynamic light scattering method” in JIS Z8828:2013 can be referred to as necessary. Five samples are produced for each level and the average value thereof is adopted.

As the beaded silica, it is preferable that a plurality of spherical silicas having an average particle diameter of 1 to 80 nm are connected through a connecting material. The upper limit of the average particle diameter of the spherical silica is preferably 70 nm or less, more preferably 60 nm or less, and still more preferably 50 nm or less. In addition, the lower limit of the average particle diameter of the spherical silica is preferably 3 nm or more, more preferably 5 nm or more, and still more preferably 7 nm or more. In the present invention, as the value of the average particle diameter of the spherical silica, a value of an average particle diameter obtained from the circle-equivalent diameter in the projection image of the spherical portion measured by a transmission electron microscope (TEM) is used.

In the beaded silica, examples of the connecting material for connecting the spherical silicas include metal oxide-containing silica. Examples of the metal oxide include an oxide of metal selected from Ca, Mg, Sr, Ba, Zn, Sn, Pb, Ni, Co, Fe, A1, In, Y, and Ti. Examples of the metal oxide-containing silica include a reactant and a mixture of these metal oxides and silica (SiO₂). With regard to the connecting material, reference can be made to the description in WO2000/015552A, the content of which is incorporated herein by reference.

The number of connected spherical silicas in the beaded silica is preferably 3 or more and more preferably 5 or more. The upper limit is preferably 1000 or less, more preferably 800 or less, and still more preferably 500 or less. The number of connected spherical silicas can be measured by TEM.

Examples of a commercially available product of a particle solution containing the beaded silica include SNOWTEX series and ORGANOSILICASOL series (methanol dispersion liquid, isopropyl alcohol dispersion liquid, ethylene glycol dispersion liquid, methyl ethyl ketone dispersion liquid, and the like; product numbers: IPA-ST-UP, MEK-ST-UP, and the like) manufactured by Nissan Chemical Corporation. In addition, as the particle solution containing the beaded silica, for example, a silica sol described in JP4328935B can be used.

An average particle diameter of the hollow silica is preferably 10 to 500 nm. The lower limit is preferably 15 nm or more, more preferably 20 nm or more, and still more preferably 25 nm or more. The upper limit is preferably 300 nm or less, more preferably 200 nm or less, and still more preferably 100 nm or less. The average particle diameter of the hollow silica is a value measured by a dynamic light scattering method. Examples of a commercially available product of a particle solution including the hollow silica include “THRULYA 4110” manufactured by JGC C&C.

A content of the inorganic particles in the composition is preferably 4% by mass or more, more preferably 6% by mass or more, and still more preferably 7% by mass or more. The upper limit is preferably 15% by mass or less, more preferably 13% by mass or less, and still more preferably 11% by mass or less. In addition, the content of the inorganic particles in the total solid content of the composition is preferably 20% by mass or more, more preferably 50% by mass or more, still more preferably 90% by mass or more, even more preferably 95% by mass or more, even still more preferably 97% by mass or more, and particularly preferably 98% by mass or more. The upper limit may be 99.95% by mass or less, 99.9% by mass or less, or 99% by mass or less.

In a case where the silica particles are used as the inorganic particles, a content of the silica particles in the composition is preferably 4% by mass or more, more preferably 6% by mass or more, and still more preferably 7% by mass or more. The upper limit is preferably 15% by mass or less, more preferably 13% by mass or less, and still more preferably 11% by mass or less. In addition, the content of the silica particles in the total solid content of the composition is preferably 20% by mass or more, more preferably 50% by mass or more, still more preferably 90% by mass or more, even more preferably 95% by mass or more, even still more preferably 97% by mass or more, and particularly preferably 98% by mass or more. The upper limit may be 99.95% by mass or less, 99.9% by mass or less, or 99% by mass or less. In a case where the content of the silica particles is within the above-described range, it is easy to obtain a cured film with a low refractive index, a high antireflection effect, and suppressed defects.

### <<Cyclic Siloxane Compound>>

The composition according to the embodiment of the present invention contains a cyclic siloxane compound. Here, the cyclic siloxane compound refers to a cyclic compound formed by a siloxane bond.

The cyclic siloxane compound is preferably a compound represented by Formula (1).

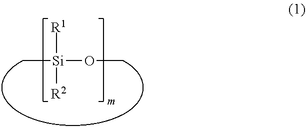

In Formula (1), R¹ and R² each independently represent a hydrogen atom or a substituent, and m represents an integer of 3 to 20.

Examples of the substituent represented by R¹ and R² in Formula (1) include an alkyl group and an aryl group, and an alkyl group is preferable.

The number of carbon atoms in the alkyl group is preferably 1 to 10, more preferably 1 to 5, still more preferably 1 to 3, and particularly preferably 1. The alkyl group may be linear, branched, or cyclic, but is preferably linear.

The number of carbon atoms in the aryl group is preferably 6 to 20, more preferably 6 to 12, and particularly preferably 6.

R¹ and R² are each preferably a hydrogen atom, a methyl group, or a phenyl group, and more preferably a methyl group.

m in Formula (1) represents an integer of 3 to 20, and is preferably an integer of 3 to 10, more preferably an integer of 3 to 8, still more preferably an integer of 3 to 6, and particularly preferably an integer of 4 to 6.

A molecular weight of the cyclic siloxane compound is preferably 1,000 or less, more preferably 800 or less, and still more preferably 600 or less. The lower limit can be 100 or more.

Specific examples of the cyclic siloxane compound include octamethylcyclotetrasiloxane, decamethylcyclopentasiloxane, dodecamethylcyclohexasiloxane, and hexamethylcyclotrisiloxane, and at least one selected from octamethylcyclotetrasiloxane, decamethylcyclopentasiloxane, or dodecamethylcyclohexasiloxane is preferable.

The composition according to the embodiment of the present invention may contain only one kind of cyclic siloxane compound, but it is preferable that the composition according to the embodiment of the present invention contains two or more kinds of cyclic siloxane compounds. In a case of containing two or more kinds of cyclic siloxane compounds, it is preferable to contain a compound in which m in Formula (1) is 3 or 4 (preferably, m is 4) and a compound in which m in Formula (1) is an integer of 5 or more (preferably, a compound in which m is an integer of 5 to 10, more preferably, a compound in which m is an integer of 5 to 8, and still more preferably, a compound in which m is 5 or 6). In addition, as a proportion of the compound in which m in Formula (1) is 3 or 4 and the compound in which m in Formula (1) is an integer of 5 or more, a content of the compound in which m in Formula (1) is an integer of 5 or more is preferably 10 to 1000 parts by mass, more preferably 25 to 750 parts by mass, and still more preferably 50 to 500 parts by mass with respect to 100 parts by mass of the compound in which m in Formula (1) is 3 or 4.

The cyclic siloxane compound preferably includes at least one selected from octamethylcyclotetrasiloxane, decamethylcyclopentasiloxane, or dodecamethylcyclohexasiloxane, and more preferably includes octamethylcyclotetrasiloxane, decamethylcyclopentasiloxane, and dodecamethylcyclohexasiloxane.

In addition, the cyclic siloxane compound is preferably at least one selected from octamethylcyclotetrasiloxane, decamethylcyclopentasiloxane, or dodecamethylcyclohexasiloxane, and more preferably consists of octamethylcyclotetrasiloxane, decamethylcyclopentasiloxane, and dodecamethylcyclohexasiloxane.

In a case where a cyclic siloxane compound including octamethylcyclotetrasiloxane, decamethylcyclopentasiloxane, and dodecamethylcyclohexasiloxane is used, a proportion of the octamethylcyclotetrasiloxane, decamethylcyclopentasiloxane, and dodecamethylcyclohexasiloxane is preferably 1 to 100 parts by mass of octamethylcyclotetrasiloxane and 50 to 200 parts by mass of decamethylcyclopentasiloxane with respect to 100 parts by mass of dodecamethylcyclohexasiloxane. The octamethylcyclotetrasiloxane is preferably 1 to 100 parts by mass and more preferably 10 to 50 parts by mass with respect to 100 parts by mass of the dodecamethylcyclohexasiloxane. The decamethylcyclopentasiloxane is preferably 1 to 200 parts by mass and more preferably 50 to 150 parts by mass with respect to 100 parts by mass of the dodecamethylcyclohexasiloxane.

The content of the cyclic siloxane compound is 0.01 to 10 parts by mass with respect to 100 parts by mass of the silicone-based surfactant. The lower limit is preferably 0.1 parts by mass or more and more preferably 0.5 parts by mass or more. The upper limit is preferably 5 parts by mass or less, more preferably 4 parts by mass or less, and more preferably 3 parts by mass or less.

In addition, the total content of the octamethylcyclotetrasiloxane, decamethylcyclopentasiloxane, and dodecamethylcyclohexasiloxane is preferably 0.01 to 10 parts by mass with respect to 100 parts by mass of the silicone-based surfactant. The lower limit is preferably 0.1 parts by mass or more and more preferably 0.5 parts by mass or more. The upper limit is preferably 5 parts by mass or less, more preferably 4 parts by mass or less, and more preferably 3 parts by mass or less.

In addition, the content of the octamethylcyclotetrasiloxane is preferably 0.01 to 10 parts by mass with respect to 100 parts by mass of the silicone-based surfactant. The lower limit is preferably 0.03 parts by mass or more, more preferably 0.05 parts by mass or more, still more preferably 0.1 parts by mass or more, and even preferably 0.5 parts by mass or more. The upper limit is preferably 5 parts by mass or less, more preferably 4 parts by mass or less, and more preferably 3 parts by mass or less.

In addition, the content of the decamethylcyclopentasiloxane is preferably 0.01 to 10 parts by mass with respect to 100 parts by mass of the silicone-based surfactant. The lower limit is preferably 0.03 parts by mass or more, more preferably 0.05 parts by mass or more, still more preferably 0.1 parts by mass or more, and even preferably 0.5 parts by mass or more. The upper limit is preferably 5 parts by mass or less, more preferably 4 parts by mass or less, and more preferably 3 parts by mass or less.

In addition, the content of the dodecamethylcyclohexasiloxane is preferably 0.01 to 10 parts by mass with respect to 100 parts by mass of the silicone-based surfactant. The lower limit is preferably 0.03 parts by mass or more, more preferably 0.05 parts by mass or more, still more preferably 0.1 parts by mass or more, and even preferably 0.5 parts by mass or more. The upper limit is preferably 5 parts by mass or less, more preferably 4 parts by mass or less, and more preferably 3 parts by mass or less.

In a case where the composition according to the embodiment of the present invention contains two or more kinds of cyclic siloxane compounds, it is preferable that the total amount thereof is within the above-described range.

### <<Silicone-Based Surfactant>>

The composition according to the embodiment of the present invention contains a silicone-based surfactant other than the cyclic siloxane compound. The silicone-based surfactant is preferably a compound which does not include a fluorine atom. In the present specification, the silicone-based surfactant is a compound having a repeating unit including a siloxane bond in the main chain, and is a compound including a hydrophobic part and a hydrophilic part in one molecule.

A viscosity of the silicone-based surfactant at 25° C. is preferably 40 mm²/s or less, more preferably 38 mm²/s or less, and still more preferably 36 mm²/s or less. In a case where the viscosity of the silicone-based surfactant is 40 mm²/s or less, a surface condition during application is excellent. From the reason that a certain amount of chain length is required in order to function as a surfactant, the lower limit of the viscosity of the silicone-based surfactant is preferably 10 mm²/s or more, more preferably 15 mm²/s or more, still more preferably 20 mm²/s or more, and particularly preferably 25 mm²/s or more.

A hydroxyl number of the silicone-based surfactant is preferably 80 mgKOH/g or more, more preferably 90 mgKOH/g or more, still more preferably 100 mgKOH/g or more, and particularly preferably 110 mgKOH/g or more. In a case where the hydroxyl number of the silicone-based surfactant is 80 mgKOH/g or more, the effects of the present invention are more remarkably exhibited. The upper limit of the hydroxyl number of the silicone-based surfactant is preferably 200 mgKOH/g or less, more preferably 150 mgKOH/g or less, and still more preferably 130 mgKOH/g or less.

The silicone-based surfactant is preferably modified polysiloxane. Examples of the modified polysiloxane include compounds having a structure in which a substituent is introduced into a side chain and/or a terminal of polysiloxane. Examples of the substituent include a group having a functional group selected from an amino group, an epoxy group, an alicyclic epoxy group, a hydroxy group, a mercapto group, a carboxy group, a fatty acid ester group, and a fatty acid amide group, and a group having a polyether chain; and a group having a hydroxy group is preferable and a group having an alkyleneoxy group and a hydroxy group is more preferable.

The group having a hydroxy group is preferably a group represented by Formula (G-1) or a group represented by (G-2).

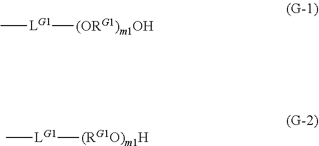

In Formula (G-1) and Formula (G-2), L^{G1} represents a single bond or a divalent linking group. Examples of the divalent linking group represented by L^{G1} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-1) and Formula (G-2), m1 represents 0 or an integer of 1 or more, and is preferably an integer of 1 to 5 and more preferably an integer of 1 to 3.

In Formula (G-1) and Formula (G-2), R^{G1} represents an alkylene group. The number of carbon atoms in the alkylene group is preferably 1 to 10, more preferably 1 to 5, still more preferably 1 to 3, and particularly preferably 2 or 3. The alkylene group represented by R^{G1} may be linear or branched. The alkylene groups represented by m1 pieces of R^{G1}'s may be the same or different from each other.

Examples of the group including a polyether chain include a group represented by Formula (G-11) and a group represented by Formula (G-12).

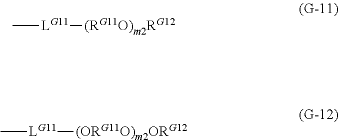

In Formula (G-11) and Formula (G-12), L^{G11} represents a single bond or a divalent linking group. Examples of the divalent linking group represented by L^{G11} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-11) and Formula (G-12), m2 represents a number of 2 or more, and is preferably 2 to 200.

In Formula (G-11) and Formula (G-12), R^{G11} represents an alkylene group. The number of carbon atoms in the alkylene group is preferably 1 to 10, more preferably 1 to 5, still more preferably 1 to 3, and particularly preferably 2 or 3. The alkylene group represented by R^{G11} may be linear or branched. The alkylene groups represented by m2 pieces of R^{G11}'s may be the same or different from each other.

In Formula (G-11) and Formula (G-12), R^{G12} represents an alkyl group or an aryl group. The number of carbon atoms in the alkyl group represented by R^{G12} is preferably 1 to 10, more preferably 1 to 5, and still more preferably 1 to 3. The alkyl group may be linear or branched. The number of carbon atoms in the aryl group represented by R^{G12} is preferably 6 to 20 and more preferably 6 to 10.

The silicone-based surfactant is preferably a carbinol-modified polysiloxane and more preferably a carbinol-modified dialkyl polysiloxane. In addition, the silicone-based surfactant is preferably dimethyl polysiloxane having an alkyleneoxy group and a hydroxy group.

The silicone-based surfactant is preferably a compound represented by Formula (Si-1) or Formula (Si-2).

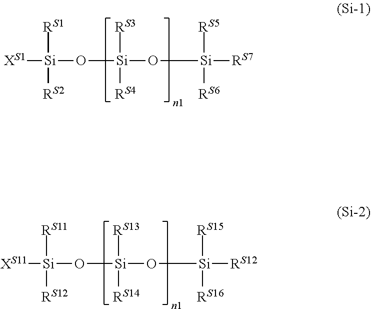

In Formula (Si-1), R^{S1} to R^{S7} each independently represent an alkyl group or an aryl group,

X^{S1} represents the group represented by Formula (G-1) or group represented by Formula (G-2) described above, and

n1 represents a number of 2 to 200.

In Formula (Si-2), R^{S11} to R^{S16} each independently represent an alkyl group or an aryl group,

X^{S11} and X^{S12} each independently represent the group represented by Formula (G-1) or group represented by Formula (G-2) described above, and

n11 represents a number of 2 to 200.

The number of carbon atoms in the alkyl group represented by R^{S1} to R^{S7} in Formula (Si-1) and in the alkyl group represented by R^{S11} to R^{S16} in Formula (Si-2) is preferably 1 to 10, more preferably 1 to 5, still more preferably 1 to 3, and particularly preferably 1. The alkyl group may be linear, branched, or cyclic, but is preferably linear.

The number of carbon atoms in the aryl group represented by R^{S1} to R^{S7} in Formula (Si-1) and in the aryl group represented by R^{S11} to R^{S16} in Formula (Si-2) is preferably 6 to 20, more preferably 6 to 12, and particularly preferably 6.

R^{S1} to R^{S7} and R^{S11} to R^{S16} are preferably a methyl group or a phenyl group and more preferably a methyl group.

Specific examples of the silicone-based surfactant include a compounds having the following structure.

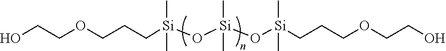

Examples of a commercially available product of the silicone-based surfactant include: DC3PA, SH7PA, DC11PA, SH21PA, SH28PA, SH29PA, SH30PA, SH8400, SH 8400 FLUID, FZ-2122, 67 Additive, 74 Additive, M Additive, and SF 8419 OIL (all of which are manufactured by Dow. TORAY); TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-333, BYK-3760, and BYK-UV3510 (all of which are manufactured by BYK Chemie).

A content of the silicone-based surfactant in the composition is preferably 1 to 2,000 ppm by mass. The lower limit is preferably 3 ppm by mass or more and more preferably 5 ppm by mass or more. The upper limit is preferably 1,000 ppm by mass or less and more preferably 500 ppm by mass or less.

### <<Other Surfactants>>

The composition according to the embodiment of the present invention may contain a surfactant other than the silicone-based surfactant (hereinafter, also referred to as other surfactants). Examples of the other surfactants include a fluorine-based surfactant, a nonionic surfactant, a cationic surfactant, and an anionic surfactant.

Examples of the fluorine-based surfactant include surfactants described in paragraphs 0060 to 0064 of JP2014-041318A (paragraphs 0060 to 0064 of the corresponding WO2014/017669A) and the like, surfactants described in paragraphs 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-01, R-40, R-40-LM, R-41, R-41-LM, RS-43, R-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FL, 710FM, 710FS, and FTX-218 (all of which are manufactured by NEOS COMPANY LIMITED).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

It is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

As the fluorine-based surfactant, a block polymer can also be used. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraphs 0016 to 0037 of JP2010-032698A, or the following compounds are also exemplified as the fluorine-based surfactant used in the present invention.

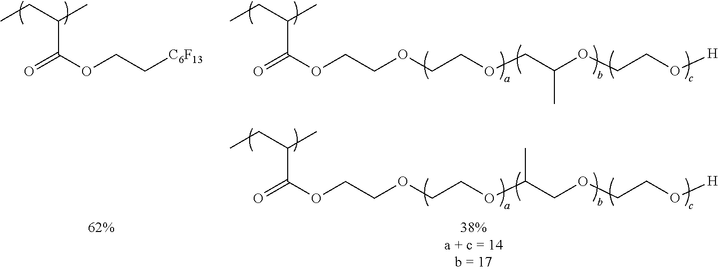

A weight-average molecular weight of the compound is preferably 3,000 to 50,000 and, for example, 14,000. In the compound, “%” representing the proportion of a repeating unit is mol %.

In addition, as the fluorine-based surfactant, a fluorine-containing polymer having an ethylenically unsaturated bond-containing group at a side chain can also be used. Specific examples thereof include compounds described in paragraphs 0050 to 0090 and paragraphs 0289 to 0295 of JP2010-164965A, and MEGAFACE RS-101, RS-102, RS-718K, and RS-72-K manufactured by DIC Corporation. In addition, as the fluorine-based surfactant, a compound described in paragraphs 0015 to 0158 of JP2015-117327A can also be used.

In addition, from the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

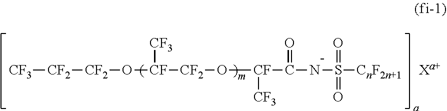

In Formula (fi-1), m represents 1 or 2, n represents an integer of 1 to 4, a represents 1 or 2, and X^{a+} represents an a-valent metal ion, a primary ammonium ion, a secondary ammonium ion, a tertiary ammonium ion, a quaternary ammonium ion, or NH₄⁺.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the cationic surfactant include a tetraalkylammonium salt, an alkylamine salt, a benzalkonium salt, an alkylpyridium salt, and an imidazolium salt. Specific examples thereof include dihydroxyethylstearylamine, 2-heptadecenyl-hydroxyethylimidazoline, lauryldimethylbenzylammonium chloride, cetylpyridinium chloride, and stealamidemethylpyridium chloride.

Examples of the anionic surfactant include dodecylbenzene sulfonic acid, sodium dodecylbenzene sulfonate, sodium lauryl sulfate, sodium alkyldiphenyl ether disulfonate, sodium alkylnaphthalene sulfonate, sodium dialkyl sulfosuccinate, sodium stearate, potassium oleate, sodium dioctyl sulfosuccinate, sodium polyoxyethylene alkyl ether sulfate, sodium polyoxyethylene alkylphenyl ether sulfate, sodium dialkyl sulfosuccinate, sodium stearate, sodium oleate, and sodium t-octylphenoxyethoxypolyethoxyethyl sulfate.

A content of the other surfactants in the composition is preferably 1000 ppm by mass or less, more preferably 500 ppm by mass or less, and still more preferably 100 ppm by mass or less. It is also preferable that the composition according to the embodiment of the present invention does not contain the other surfactants.

### <<Solvent>>

The composition according to the embodiment of the present invention preferably contains a solvent. Examples of the solvent include an organic solvent and water, and it is preferable to include at least an organic solvent. Examples of the organic solvent include an aliphatic hydrocarbon-based solvent, a halogenated hydrocarbon-based solvent, an alcohol-based solvent, an ether-based solvent, an ester-based solvent, a ketone-based solvent, a nitrile-based solvent, an amide-based solvent, a sulfoxide-based solvent, and an aromatic solvent.

Examples of the aliphatic hydrocarbon-based solvent include hexane, cyclohexane, methylcyclohexane, pentane, cyclopentane, heptane, and octane.

Examples of the halogenated hydrocarbon-based solvent include methylene chloride, chloroform, ethane dichloride, carbon tetrachloride, trichloroethylene, tetrachloroethylene, epichlorohydrin, monochlorobenzene, o-dichlorobenzene, allyl chloride, methyl monochloroacetate, ethyl monochloroacetate, monochloroacetic acid, trichloroacetic acid, methyl bromide, and tri(tetra)chlorethylene.

Examples of the alcohol-based solvent include methanol, ethanol, 1-propanol, 2-propanol, 2-butanol, ethylene glycol, propylene glycol, glycerin, 1,6-hexanediol, cyclohexanediol, sorbitol, xylitol, 2-methyl-2,4-pentanediol, 3-methoxy-1-butanol, 1,3-butanediol, and 1,4-butanediol.

Examples of the ether-based solvent include dimethyl ether, diethyl ether, diisopropyl ether, dibutyl ether, t-butyl methyl ether, cyclohexylmethyl ether, anisole, tetrahydrofuran, diethylene glycol, triethylene glycol, polyethylene glycol, dipropylene glycol, ethylene glycol monomethyl ether, ethylene glycol monobutyl ether, ethylene glycol monophenyl ether, propylene glycol monomethyl ether, propylene glycol monoethyl ether, propylene glycol monopropyl ether, propylene glycol monobutyl ether, diethylene glycol monomethyl ether, diethylene glycol monoethyl ether, diethylene glycol monopropyl ether, diethylene glycol monobutyl ether, diethylene glycol dimethyl ether, diethylene glycol diethyl ether, diethylene glycol dipropyl ether, diethylene glycol dibutyl ether, dipropylene glycol monomethyl ether, dipropylene glycol dimethyl ether, dipropylene glycol monoethyl ether, dipropylene glycol monopropyl ether, dipropylene glycol monobutyl ether, dipropylene glycol methyl-n-propyl ether, triethylene glycol monomethyl ether, triethylene glycol monobutyl ether, tripropylene glycol monomethyl ether, tripropylene glycol monobutyl ether, tetraethylene glycol dimethyl ether, polyethylene glycol monomethyl ether, and polyethylene glycol dimethyl ether.

Examples of the ester-based solvent include propylene carbonate, dipropylene, 1,4-butanediol diacetate, 1,3-butylene glycol diacetate, 1,6-hexanediol diacetate, cyclohexanol acetate, dipropylene glycol methyl ether acetate, methyl acetate, ethyl acetate, isopropyl acetate, n-propyl acetate, butyl acetate, ethylene glycol monomethyl ether acetate, propylene glycol monomethyl ether acetate, 3-methoxybutyl acetate, ethylene glycol monobutyl ether acetate, diethylene glycol monoethyl ether acetate, diethylene glycol monobutyl ether acetate, and triacetin.

Examples of the ketone-based solvent include acetone, methyl ethyl ketone, methyl isobutyl ketone, cyclopentanone, cyclohexanone, and 2-heptanone.

Examples of the nitrile-based solvent include acetonitrile.

Examples of the amide-based solvent include N,N-dimethylformamide, 1-methyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropaneamide, hexamethylphosphoric triamide, 3-methoxy-N,N-dimethylpropaneamide, and 3-butoxy-N,N-dimethylpropaneamide.

Examples of the sulfoxide-based solvent include dimethyl sulfoxide.

Examples of the aromatic solvent include benzene and toluene.

As the solvent, from the reason that it is easy to form a film in which generation of thickness unevenness or defects is further suppressed, it is preferable to use a solvent including an alcohol-based solvent. The alcohol-based solvent is preferably at least one selected from methanol, ethanol, 1-propanol, 2-propanol, or 2-butanol, and more preferably at least one selected from methanol and ethanol. Among these, the alcohol-based solvent preferably includes at least methanol, and from the reason that it is easy to form a film in which generation of defects is further suppressed, more preferably includes methanol and ethanol.

A content of the solvent in the composition is preferably 70% to 99% by mass. The upper limit is preferably 93% by mass or less, more preferably 92% by mass or less, and still more preferably 90% by mass or less. The lower limit is preferably 75% by mass or more, more preferably 80% by mass or more, and still more preferably 85% by mass or more. The solvent may be used alone or in combination of two or more kinds thereof. In a case where two or more kinds thereof are used, the total amount thereof is preferably within the above-described range.

In addition, the content of the alcohol-based solvent in the total amount of the solvent is preferably 0.1% to 10% by mass. The upper limit is preferably 8% by mass or less, more preferably 6% by mass or less, and still more preferably 4% by mass or less. The lower limit is preferably 0.3% by mass or more, more preferably 0.5% by mass or more, and still more preferably 1% by mass or more. The alcohol-based solvent may be used singly or in combination of two or more kinds thereof. In a case where the composition according to the embodiment of the present invention contains two or more kinds of alcohol-based solvents, it is preferable that the total amount thereof is within the above-described range.

As the solvent, a solvent including a solvent A1 which has a boiling point of 190° C. or higher and 280° C. or lower is preferably used. In the present specification, the boiling point of a solvent is a value at 1 atm (0.1 MPa).

The boiling point of the solvent A1 is preferably 200° C. or higher, more preferably 210° C. or higher, and still more preferably 220° C. or higher. In addition, the boiling point of the solvent A1 is preferably 270° C. or lower and still more preferably 265° C. or lower.

The viscosity of the solvent A1 is preferably 10 mPa's or less, more preferably 7 mPa′s or less, and still more preferably 4 mPa's or less. From the viewpoint of application properties, the lower limit of the viscosity of the solvent A1 is preferably 1.0 mPa's or more, more preferably 1.4 mPa's or more, and still more preferably 1.8 mPa's or more.

The molecular weight of the solvent A1 is preferably 100 or more, more preferably 130 or more, still more preferably 140 or more, and particularly preferably 150 or more. From the viewpoint of application properties, the upper limit is preferably 300 or less, more preferably 290 or less, still more preferably 280 or less, and particularly preferably 270 or less.

The solubility parameter of the solvent A1 is preferably 8.5 to 13.3 (cal/cm³)^{0.5}. The upper limit is preferably 12.5 (cal/cm³)^{0.5} or less, more preferably 11.5 (cal/cm³)^{0.5} or less, and still more preferably 10.5 (cal/cm³)^{0.5} or less. The lower limit is preferably 8.7 (cal/cm³)^{0.5} or more, more preferably 8.9 (cal/cm³)^{0.5} or more, and still more preferably 9.1 (cal/cm³)^{0.5} or more. In a case where the solubility parameter of the solvent A1 is within the above-described range, high affinity with the inorganic particles such as silica particles is obtained, and excellent application properties are easily obtained. 1 (cal/cm³)^{0.5} is 2.0455 MPa^{0.5}. In addition, the solubility parameter of a solvent is a value calculated by HSPiP.

In the present specification, the Hansen solubility parameter is used as the solubility parameter of the solvent. Specifically, a value calculated by using the Hansen solubility parameter software “HSPiP 5.0.09” is used.

The solvent A1 is preferably an aprotic solvent. In a case where an aprotic solvent is used as the solvent A1, aggregation of the inorganic particles such as silica particles during film formation can be more effectively suppressed, and it is easy to form a film in which generation of thickness unevenness or defects is further suppressed.

The solvent A1 is preferably an ether-based solvent or an ester-based solvent, and more preferably an ester-based solvent. In addition, the ester-based solvent used as the solvent A1 is preferably a compound not including a hydroxy group or a terminal alkoxy group. By using an ester-based solvent not having such a functional group, it is easy to form a film in which generation of thickness unevenness or defects is further suppressed.

From the viewpoint that high affinity with the inorganic particles such as silica particles is obtained, and excellent application properties are easily obtained, it is preferable that the solvent A1 is at least one selected from alkylene diol diacetate or cyclic carbonate. Examples of the alkylenediol diacetate include propylene glycol diacetate, 1,4-butanediol diacetate, 1,3-butylene glycol diacetate, and 1,6-hexanediol diacetate. Examples of the cyclic carbonate include propylene carbonate and ethylene carbonate.

Specific examples of the solvent A1 include propylene carbonate (boiling point: 240° C.), ethylene carbonate (boiling point: 260° C.), propylene glycol diacetate (boiling point: 190° C.), dipropylene glycol methyl-n-propyl ether (boiling point: 203° C.), dipropylene glycol methyl ether acetate (boiling point: 213° C.), 1,4-butanediol diacetate (boiling point: 232° C.), 1,3-butylene glycol diacetate (boiling point: 232° C.), 1,6-hexanediol diacetate (boiling point: 260° C.), diethylene glycol monoethyl ether acetate (boiling point: 217° C.), diethylene glycol monobutyl ether acetate (boiling point: 247° C.), triacetin (boiling point: 260° C.), dipropylene glycol monomethyl ether (boiling point: 190° C.), diethylene glycol monoethyl ether (boiling point: 202° C.), dipropylene glycol monopropyl ether (boiling point: 212° C.), dipropylene glycol monobutyl ether (boiling point: 229° C.), tripropylene glycol monomethyl ether (boiling point: 242° C.), and tripropylene glycol monobutyl ether (boiling point: 274° C.).

A content of the above-described solvent A1 in the solvent contained in the composition according to the embodiment of the present invention is preferably 3% by mass or more, more preferably 4% by mass or more, and still more preferably 5% by mass or more. The upper limit is preferably 20% by mass or less, more preferably 15% by mass or less, and still more preferably 12% by mass or less. The solvent A1 may be used singly or in a combination of two or more kinds thereof. In a case where the composition according to the embodiment of the present invention includes two or more kinds of the solvent A1, it is preferable that the total amount thereof is within the above-described range.

It is also preferable that the solvent contained in the composition according to the embodiment of the present invention further contains a solvent A2 having a boiling point of 110° C. or higher and lower than 190° C., in addition to the above-described solvent A1. According to this aspect, it is easy to form a film in which drying properties of the composition are appropriately increased and the thickness unevenness is further suppressed.

The boiling point of the solvent A2 is preferably 115° C. or higher, more preferably 120° C. or higher, and still more preferably 130° C. or higher. In addition, the boiling point of the solvent A2 is preferably 170° C. or lower and still more preferably 150° C. or lower. In a case where the boiling point of the solvent A2 is within the above-described range, the above-described effects are easily obtained more remarkably.

From the reason that the above-described effects are easily obtained more remarkably, the molecular weight of the solvent A2 is preferably 100 or more, more preferably 130 or more, still more preferably 140 or more, and particularly preferably 150 or more. From the viewpoint of application properties, the upper limit is preferably 300 or less, more preferably 290 or less, still more preferably 280 or less, and particularly preferably 270 or less.

The solubility parameter of the solvent A2 is preferably 9.0 to 11.4 (cal/cm³)^{0.5}. The upper limit is preferably 11.0 (cal/cm³)^{0.5} or less, more preferably 10.6 (cal/cm³)^{0.5} or less, and still more preferably 10.2 (cal/cm³)^{0.5} or less. The lower limit is preferably 9.2 (cal/cm³)^{0.5} or more, more preferably 9.4 (cal/cm³)^{0.5} or more, and still more preferably 9.6 (cal/cm³)^{0.5} or more. In a case where the solubility parameter of the solvent A2 is within the above-described range, high affinity with the inorganic particles such as silica particles is obtained, and excellent application properties are easily obtained. In addition, the absolute value of a difference between the solubility parameter of the solvent A1 and the solubility parameter of the solvent A2 is preferably 0.01 to 1.1 (cal/cm³)^{0.5}. The upper limit is preferably 0.9 (cal/cm³)^{0.5} or less, more preferably 0.7 (cal/cm³)^{0.5} or less, and still more preferably 0.5 (cal/cm³)^{0.5} or less. The lower limit is preferably 0.03 (cal/cm³)^{0.5} or more, more preferably 0.05 (cal/cm³)^{0.5} or more, and still more preferably 0.08 (cal/cm³)^{0.5} or more.

The solvent A2 is preferably at least one selected from an ether-based solvent or an ester-based solvent, more preferably includes at least an ester-based solvent, and still more preferably includes an ether-based solvent and an ester-based solvent. Specific examples of the solvent A2 include cyclohexanol acetate (boiling point: 173° C.), dipropylene glycol dimethyl ether (boiling point: 175° C.), butyl acetate (boiling point: 126° C.), ethylene glycol monomethyl ether acetate (boiling point: 145° C.), propylene glycol monomethyl ether acetate (boiling point: 146° C.), 3-methoxybutyl acetate (boiling point: 171° C.), propylene glycol monomethyl ether (boiling point: 120° C.), 3-methoxybutanol (boiling point: 161° C.), propylene glycol monopropyl ether (boiling point: 150° C.), propylene glycol monobutyl ether (boiling point: 170° C.), and ethylene glycol monobutyl ether acetate (boiling point: 188° C.), and from the reason that high affinity with the inorganic particles such as silica particles can be obtained and excellent application properties can be easily obtained, it is preferable to include at least propylene glycol monomethyl ether acetate.

In a case where the solvent used in the composition according to the embodiment of the present invention contains the solvent A2, a content of the solvent A2 is preferably 500 to 5000 parts by mass with respect to 100 parts by mass of the solvent A1. The upper limit is preferably 4500 parts by mass or less, more preferably 4000 parts by mass or less, and still more preferably 3500 parts by mass or less. The lower limit is preferably 600 parts by mass or more, more preferably 700 parts by mass or more, and still more preferably 750 parts by mass or more. In addition, the content of the solvent A2 in the total amount of the solvent is preferably 50% by mass or more, more preferably 60% by mass or more, and still more preferably 70% by mass or more. The upper limit is preferably 95% by mass or less, more preferably 90% by mass or less, and still more preferably 85% by mass or less. The solvent A2 may be used singly or in a combination of two or more kinds thereof. In a case where the composition according to the embodiment of the present invention contains two or more kinds of the solvent A2, it is preferable that the total amount thereof is within the above-described range.

In addition, the total content of the solvent A1 and the solvent A2 in the solvent used in the composition according to the embodiment of the present invention is preferably 62% by mass or more, more preferably 72% by mass or more, and still more preferably 82% by mass or more. The upper limit may be 100% by mass, 96% by mass or less, or 92% by mass or less.

It is also preferable that the solvent used in the composition according to the embodiment of the present invention further contains water. According to this aspect, high affinity with the inorganic particles such as silica particles is obtained, and excellent application properties are easily obtained. In a case where the solvent used in the composition according to the embodiment of the present invention further includes water, a content of the water in the total amount of the solvent is preferably 0.1% to 5% by mass. The upper limit is preferably 4% by mass or less, more preferably 2.5% by mass or less, and still more preferably 1.5% by mass or less. The lower limit is preferably 0.3% by mass or more, more preferably 0.5% by mass or more, and still more preferably 0.7% by mass or more. In a case where the content of water is within the above-described range, the above-described effects are easily obtained more remarkably.

The solvent used in the composition according to the embodiment of the present invention can further include a solvent A3 having a boiling point of higher than 280° C. According to this aspect, it is easy to form a film in which drying properties of the composition are appropriately increased and generation of thickness unevenness or defects is further suppressed. The upper limit of the boiling point of the solvent A3 is preferably 400° C. or lower, more preferably 380° C. or lower, and still more preferably 350° C. or lower. The solvent A3 is preferably at least one selected from an ether-based solvent or an ester-based solvent. Specific examples of the solvent A3 include polyethylene glycol monomethyl ether. In a case where the solvent used in the composition according to the embodiment of the present invention further includes the solvent A3, a content of the solvent A3 in the total amount of the solvent is preferably 0.5% to 15% by mass. The upper limit is preferably 10% by mass or less, more preferably 8% by mass or less, and still more preferably 6% by mass or less. The lower limit is preferably 1% by mass or more, more preferably 1.5% by mass or more, and still more preferably 2% by mass or more. In addition, it is also preferable that the solvent used in the composition according to the embodiment of the present invention does not substantially contain the solvent A3. The case where the solvent does not substantially contain the solvent A3 means that the content of the solvent A3 in the total amount of the solvent is 0.1% by mass or less, preferably 0.05% by mass or less, more preferably 0.01% by mass or less, and still more preferably 0% by mass.

In the solvent used in the composition according to the embodiment of the present invention, a content of a compound having a molecular weight (weight-average molecular weight in a case of a polymer) of more than 300 is preferably 10% by mass or less, more preferably 8% by mass or less, still more preferably 5% by mass or less, even more preferably 3% by mass or less, and particularly preferably 1% by mass or less. According to this aspect, it is easy to form a film in which generation of thickness unevenness or defects is further suppressed.

In the solvent used in the composition according to the embodiment of the present invention, a content of a compound having a viscosity of more than 10 mPa's at 25° C. is preferably 10% by mass or less, more preferably 8% by mass or less, still more preferably 5% by mass or less, even more preferably 3% by mass or less, and particularly preferably 1% by mass or less. According to this aspect, it is easy to form a film in which generation of thickness unevenness or defects is further suppressed.

### <<Dispersant>>

The composition according to the embodiment of the present invention can contain a dispersant. Examples of the dispersant include polymer dispersants (for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate), polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant adsorbs on a surface of particles and acts to prevent reaggregation. Therefore, examples of a preferred structure of the polymer dispersant include a terminal-modified polymer, a graft polymer, and a block polymer, each of which has an anchor site for adsorbing on the particle surface. A commercially available product can also be used as the dispersant. Examples thereof include products described in paragraph 0050 of WO2016/190374A, the contents of which are incorporated herein by reference.

A content of the dispersant is preferably 1 to 100 parts by mass, more preferably 3 to 100 parts by mass, and still more preferably 5 to 80 parts by mass with respect to 100 parts by mass of the inorganic particles. In addition, the content of the dispersant in the total solid content of the composition is preferably 1 to 30% by mass. As the dispersant, one kind may be included, or two or more kinds may be included. In a case where the composition according to the embodiment of the present invention contains two or more kinds of the dispersants, it is preferable that the total amount thereof is within the above-described range.

### <<Polymerizable Monomer>

The composition according to the embodiment of the present invention may contain a polymerizable monomer. As the polymerizable monomer, a well-known compound which is crosslinkable by a radical, an acid, or heat can be used. The polymerizable monomer in the present invention is preferably a radically polymerizable monomer. The radically polymerizable monomer is preferably a compound having an ethylenically unsaturated bond-containing group.

A molecular weight of the polymerizable monomer is preferably 100 to 3,000. The upper limit is more preferably 2,000 or less and still more preferably 1,500 or less. The lower limit is more preferably 150 or more and still more preferably 250 or more.

The polymerizable monomer is preferably a compound having two or more ethylenically unsaturated bond-containing groups, and more preferably a compound having three or more ethylenically unsaturated bond-containing groups. The upper limit of the number of the ethylenically unsaturated bond-containing groups is, for example, preferably 15 or less and more preferably 6 or less. Examples of the ethylenically unsaturated bond-containing group include a vinyl group, a styrene group, a (meth)allyl group, and a (meth)acryloyl group, and a (meth)acryloyl group is preferable. The polymerizable monomer is preferably a (meth)acrylate compound having 3 to 15 functional groups and more preferably a (meth)acrylate compound having 3 to 6 functional groups. Specific examples of the polymerizable monomer include compounds described in paragraphs 0059 to 0079 of WO2016/190374A.

As the polymerizable monomer, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd. and NK ESTER A-DPH-12E manufactured by Shin-Nakamura Chemical Co., Ltd.), a compound having a structure in which a (meth)acryloyl group of these compounds is bonded through an ethylene glycol residue and/or a propylene glycol residue (for example, SR454 and SR499 available from Sartomer Japan Inc.), diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), or the like can be used.

In addition, as the polymerizable monomer, it is also possible to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable monomer, a compound having an acid group can also be used. Examples of the acid group include a carboxy group, a sulfo group, and a phosphoric acid group, and a carboxy group is preferable. Examples of a commercially available product of the polymerizable monomer having an acid group include ARONIX M-510, M-520, and ARONIX TO-2349 (manufactured by TOAGOSEI CO., LTD). An acid value of the polymerizable monomer having an acid group is preferably 0.1 to 40 mgKOH/g and more preferably 5 to 30 mgKOH/g. In a case where the acid value of the polymerizable monomer is 0.1 mgKOH/g or more, solubility in a developer is good, and in a case where the acid value of the polymerizable monomer is 40 mgKOH/g or less, it is advantageous in production and handling.

As the polymerizable monomer, a compound having a caprolactone structure can also be used. Examples of the polymerizable monomer having a caprolactone structure include DPCA-20, DPCA-30, DPCA-60, and DPCA-120, each of which is commercially available as KAYARAD DPCA series from Nippon Kayaku Co., Ltd.

As the polymerizable monomer, a polymerizable monomer having an alkyleneoxy group can also be used. The polymerizable monomer having an alkyleneoxy group is preferably a polymerizable monomer having an ethyleneoxy group and/or a propyleneoxy group, more preferably a polymerizable monomer having an ethyleneoxy group, and still more preferably a trifunctional to hexafunctional (meth)acrylate compound having 4 to 20 ethyleneoxy groups. Examples of a commercially available product of the polymerizable monomer having an alkyleneoxy group include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable monomer, a polymerizable monomer having a fluorene skeleton can also be used. Examples of a commercially available product of the polymerizable monomer having a fluorene skeleton include OGSOL EA-0200 and EA-0300 (manufactured by Osaka Gas Chemicals Co., Ltd., a (meth)acrylate monomer having a fluorene skeleton).

As the polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

In a case where the composition according to the embodiment of the present invention contains the polymerizable monomer, a content of the polymerizable monomer in the composition is preferably 0.1% by mass or more, more preferably 0.2% by mass or more, and still more preferably 0.5% by mass or more. The upper limit is preferably 10% by mass or less, more preferably 5% by mass or less, and still more preferably 3% by mass or less. In addition, the content of the polymerizable monomer in the total solid content of the composition is preferably 1% by mass or more, more preferably 2% by mass or more, and still more preferably 5% by mass or more. The upper limit is preferably 30% by mass or less, more preferably 25% by mass or less, and still more preferably 20% by mass or less. The composition according to the embodiment of the present invention may contain only one kind of polymerizable monomer, or may contain two or more kinds thereof. In a case where the composition according to the embodiment of the present invention contains two or more kinds of polymerizable monomers, it is preferable that the total amount thereof is within the above-described range.

In addition, it is also preferable that the composition according to the embodiment of the present invention does not substantially contain the polymerizable monomer. In a case where the composition according to the embodiment of the present invention does not substantially contain the polymerizable monomer, a film having a lower refractive index is easily formed. Furthermore, it is easy to form a film having a small haze. The case where the composition according to the embodiment of the present invention does not substantially contain the polymerizable monomer means that the content of the polymerizable monomer in the total solid content of the composition according to the embodiment of the present invention is 0.05% by mass or less, preferably 0.01% by mass or less, and more preferably 0% by mass.

### <<Photopolymerization Initiator>>

The composition according to the embodiment of the present invention can contain a photopolymerization initiator. In a case where the composition according to the embodiment of the present invention contains the polymerizable monomer and the photopolymerization initiator, the composition according to the embodiment of the present invention can be preferably used as a composition for forming a pattern by a photolithography method.

Examples of the photopolymerization initiator include a halogenated hydrocarbon derivative (for example, a compound having a triazine skeleton or a compound having an oxadiazole skeleton), an acylphosphine compound, a hexaarylbiimidazole compound, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a hexaarylbiimidazole compound, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, peroxide initiators described in JP2019-167313A, aminoacetophenone-based initiators described in JP2020-055992A, oxime-based photopolymerization initiators described in JP2013-190459A, polymers described in JP2020-172619A, and the compound represented by Formula 1 described in WO2020/152120A, the contents of which are incorporated herein by reference.

Specific examples of the hexaarylbiimidazole compound include 2,2′,4-tris(2-chlorophenyl)-5-(3,4-dimethoxyphenyl)-4,5-diphenyl-1,1′-biimidazole.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraphs 0025 to 0038 of WO2017/164127A, the compounds described in WO2013/167515A, the compounds described in JP5430746B, and compounds described in JP5647738B. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, 2-ethoxycarbonyloxyimino-1-phenylpropane-1-one, and 1-[4-(phenylthio)phenyl]-3-cyclohexyl-propane-1,2-dione-2-(O-acetyloxime). Examples of a commercially available product thereof include Irgacure OXE01, Irgacure OXE02, Irgacure OXE03, and Irgacure OXE04 (all of which are manufactured by BASF SE), TR-PBG-304 and TR-PBG-327 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, compounds described in JP6636081B, and compounds described in KR10-2016-0109444A.

An oxime compound having a skeleton in which at least one benzene ring of a carbazole ring is a naphthalene ring can also be used as the photopolymerization initiator. Specific examples of such an oxime compound include the compounds described in WO2013/083505A.

An oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include a compound described in paragraphs 0031 to 0047 of JP2013-114249A and paragraphs 0008 to 0012 and 0070 to 0079 of JP2014-137466A, a compound described in paragraphs 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

An oxime compound in which a substituent having a hydroxy group is bonded to a carbazole skeleton can also be used as the photopolymerization initiator. Examples of such a photopolymerization initiator include compounds described in WO2019/088055A.

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2,000 to 300,000, and particularly preferably 5,000 to 200,000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the composition can be improved. Specific examples of the bifunctional or tri- or higher functional photoradical polymerization initiator include dimers of the oxime compounds described in JP2010-527339A, JP2011-524436A, WO2015/004565A, paragraphs 0407 to 0412 of JP2016-532675A, and paragraphs 0039 to 0055 of WO2017/033680A; the compound (E) and compound (G) described in JP2013-522445A; Cmpd 1 to 7 described in WO2016/034963A; the oxime ester-based photoinitiators described in paragraph 0007 of JP2017-523465A; the photoinitiators described in paragraphs 0020 to 0033 of JP2017-167399A; the photopolymerization initiator (A) described in paragraphs 0017 to 0026 of JP2017-151342A; and the oxime ester-based photoinitiators described in JP6469669B.

In a case where the composition according to the embodiment of the present invention contains the photopolymerization initiator, a content of the photopolymerization initiator in the composition is preferably 0.1% by mass or more, more preferably 0.2% by mass or more, and still more preferably 0.5% by mass or more. The upper limit is preferably 10% by mass or less, more preferably 5% by mass or less, and still more preferably 3% by mass or less. In addition, the content of the photopolymerization initiator in the total solid content of the composition is preferably 1% by mass or more, more preferably 2% by mass or more, and still more preferably 5% by mass or more. The upper limit is preferably 30% by mass or less, more preferably 25% by mass or less, and still more preferably 20% by mass or less. In addition, the content of the photopolymerization initiator is preferably 10 to 1000 parts by mass with respect to 100 parts by mass of the polymerizable monomer. The upper limit is preferably 500 parts by mass or less, more preferably 300 parts by mass or less, and still more preferably 100 parts by mass or less. The lower limit is preferably 20 parts by mass or more, more preferably 40 parts by mass or more, and still more preferably 60 parts by mass or more. The composition according to the embodiment of the present invention may contain only one kind of the photopolymerization initiator, or may contain two or more kinds thereof. In a case where the composition according to the embodiment of the present invention contains two or more kinds of photopolymerization initiators, it is preferable that the total amount thereof is within the above-described range.

In addition, it is also preferable that the composition according to the embodiment of the present invention does not substantially contain the photopolymerization initiator. The case where the composition according to the embodiment of the present invention does not substantially contain the photopolymerization initiator means that the content of the photopolymerization initiator in the total solid content of the composition is 0.005% by mass or less, preferably 0.001% by mass or less, and more preferably 0% by mass.

### <<Resin>>

The composition according to the embodiment of the present invention may contain a resin. A weight-average molecular weight (Mw) of the resin is preferably 3,000 to 2,000,000. The upper limit is preferably 1,000,000 or less and more preferably 500,000 or less. The lower limit is preferably 4,000 or more and more preferably 5,000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide resin, a polyamideimide resin, a polyolefin resin, a cyclic olefin resin, a polyester resin, a styrene resin, a vinyl acetate resin, a polyvinyl alcohol resin, a polyvinyl acetal resin, a polyurethane resin, and a polyurea resin. These resins may be used singly or as a mixture of two or more kinds thereof. From the viewpoint of improving heat resistance, as the cyclic olefin resin, a norbornene resin is preferable. Examples of a commercially available product of the norbornene resin include ARTON series (for example, ARTON F4520) manufactured by JSR Corporation. In addition, as the resin, resins described in Examples of WO2016/088645A, resins described in JP2017-057265A, resins described in JP2017-032685A, resins described in JP2017-075248A, resins described in JP2017-066240A, resins described in JP2017-167513A, resins described in JP2017-173787A, resins described in paragraphs 0041 to 0060 of JP2017-206689A, resins paragraphs 0022 to 0071 of JP2018-010856A, block polyisocyanate resins described in JP2016-222891A, resins described in JP2020-122052A, resins described in JP2020-111656A, resins described in JP2020-139021A, and resins including a constitutional unit having a ring structure in the main chain and a constitutional unit having a biphenyl group in the side chain, which are described in JP2017-138503A, can also be used. In addition, as the resin, a resin having a fluorene skeleton can also be preferably used. With regard to the resin having a fluorene skeleton, reference can be made to the description in US2017/0102610A, the content of which is incorporated herein by reference. In addition, as the resin, resins described in paragraphs 0199 to 0233 of JP2020-186373A, alkali-soluble resins described in JP2020-186325A, and resins represented by Formula 1, described in KR10-2020-0078339A, can also be used.

It is also preferable to use a resin having an acid group as the resin. According to this aspect, developability can be further improved in a case of forming a pattern by a photolithography method. Examples of the acid group include a carboxy group, a phosphoric acid group, a sulfo group, and a phenolic hydroxyl group, and a carboxy group is preferable. The resin having an acid group can be used, for example, as an alkali-soluble resin.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. A weight-average molecular weight (Mw) of the resin having an acid group is preferably 5,000 to 100,000. In addition, a number-average molecular weight (Mn) of the resin having an acid group is preferably 1,000 to 20,000.

In a case where the composition according to the embodiment of the present invention contains a resin, a content of the resin in the composition is preferably 0.01% by mass or more, more preferably 0.05% by mass or more, and still more preferably 0.1% by mass or more. The upper limit is preferably 2% by mass or less, more preferably 1% by mass or less, and still more preferably 0.5% by mass or less. In addition, the content of the resin in the total solid content of the composition is preferably 0.2% by mass or more, more preferably 0.7% by mass or more, and still more preferably 1.2% by mass or more. The upper limit is preferably 18% by mass or less, more preferably 12% by mass or less, and still more preferably 5% by mass or less. The composition according to the embodiment of the present invention may contain only one kind of resin, or may contain two or more kinds thereof. In a case where the composition according to the embodiment of the present invention contains two or more kinds of resins, it is preferable that the total amount thereof is within the above-described range.

### <<Adhesion Improver>>

The composition according to the embodiment of the present invention may contain an adhesion improver. By containing the adhesion improver, a film having excellent adhesiveness to the support can be formed. Suitable examples of the adhesion improver include adhesion improvers described in JP1993-011439A (JP-H05-011439A), JP1993-341532A (JP-H05-341532A), JP1994-043638A (JP-H06-043638A), and the like. Specific examples thereof include benzimidazole, benzoxazole, benzthiazole, 2-mercaptobenzimidazole, 2-mercaptobenzoxazole, 2-mercaptobenzthiazole, 3-morpholinomethyl-1-phenyl-triazole-2-thione, 3-morpholinomethyl-5-phenyl-oxadiazole-2-thione, 5-amino-3-morpholinomethyl-thiadiazole-2-thione, 2-mercapto-5-methylthio-thiazole, triazole, tetrazole, benzotriazole, carboxybenzotriazole, amino group-containing benzotriazole, and a silane coupling agent. As the adhesion improver, a silane coupling agent is preferable. In this specification, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable.

The silane coupling agent is preferably a compound having an alkoxysilyl group. Examples of the functional group other than a hydrolyzable group include a vinyl group, a (meth)allyl group, a (meth)acryloyl group, a mercapto group, an epoxy group, an oxetanyl group, an amino group, an ureide group, a sulfide group, an isocyanate group, and a phenyl group. Among these, an amino group, a (meth)acryloyl group, or an epoxy group is preferable.

Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropyl methyldimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include compounds described in paragraphs 0018 to 0036 of JP2009-288703A and compounds described in paragraphs 0056 to 0066 of JP2009-242604A, the contents of which are incorporated herein by reference.

In a case where the composition according to the embodiment of the present invention contains an adhesion improver, a content of the adhesion improver in the total solid content of the composition is preferably 0.001% by mass or more, more preferably 0.01% by mass or more, and particularly preferably 0.1% by mass or more. The upper limit is preferably 20% by mass or less, more preferably 10% by mass or less, and particularly preferably 5% by mass or less. The composition according to the embodiment of the present invention may contain only one kind of adhesion improver, or may contain two or more kinds thereof. In a case where the composition according to the embodiment of the present invention contains two or more kinds of adhesion improvers, it is preferable that the total amount thereof is within the above-described range. In addition, it is also preferable that the composition according to the embodiment of the present invention does not substantially contain the adhesion improver. The case where the composition according to the embodiment of the present invention does not substantially contain the adhesion improver means that the content of the adhesion improver in the total solid content of the composition is 0.0005% by mass or less, preferably 0.0001% by mass or less and more preferably 0% by mass.

### <<Colorant>>

The composition according to the embodiment of the present invention may contain a colorant. Examples of the colorant include a green colorant, a red colorant, a yellow colorant, a violet colorant, a blue colorant, an orange colorant, and a black colorant.

The colorant may be a pigment or a dye. An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less.

A content of the colorant in the total solid content of the composition is preferably 10% by mass or less, more preferably 5% by mass or less, and particularly preferably 1% by mass or less. The composition according to the embodiment of the present invention may contain only one kind of colorant, or may contain two or more kinds thereof. In a case where the composition according to the embodiment of the present invention contains two or more kinds of the colorants, it is preferable that the total amount thereof is within the above-described range.

In addition, it is also preferable that the composition according to the embodiment of the present invention does not substantially contain the colorant. The case where the composition according to the embodiment of the present invention does not substantially contain the colorant means that the content of the colorant in the total solid content of the composition is 0.1% by mass or less, preferably 0.05% by mass or less and more preferably 0% by mass.

### <<Other Components>>

Optionally, the composition according to the embodiment of the present invention may further contain a sensitizer, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph 0183 of JP2012-003225A (corresponding to paragraph 0237 of US2013/0034812A) and paragraphs 0101 to 0104 and 0107 to 0109 of JP2008-250074A, the contents of which are incorporated herein by reference. In addition, optionally, the composition according to the embodiment of the present invention may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

From the viewpoint of environmental regulation, the use of perfluoroalkyl sulfonic acid and a salt thereof and use of perfluoroalkyl carboxylic acid and a salt thereof may be restricted. In the composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably 0.05 ppb to 500 ppb, and still more preferably 0.1 ppb to 300 ppb with respect to the total solid content of the composition according to the embodiment of the present invention. The composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The composition according to the embodiment of the present invention may contain the perfluoroalkyl sulfonic acid and a salt thereof and the perfluoroalkyl carboxylic acid and a salt thereof within the maximum allowable range.

<Storage container>

A storage container of the composition is not particularly limited, and a well-known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A. In addition, for the purpose of preventing metal elution from the container interior wall, improving storage stability of the composition, and suppressing the alteration of components, it is also preferable that the container interior wall is formed of glass, stainless steel, or the like.

### <Manufacturing Method of Composition>

The composition according to the embodiment of the present invention can be produced by mixing the above-described components. During the production of the composition, all the components may be dissolved or dispersed in a solvent at the same time to produce the composition. Optionally, two or more solutions or dispersion liquids in which the respective components are appropriately blended may be prepared, and the solutions or dispersion liquids may be mixed with each other during use (during application) to produce the composition.

During the production of the composition according to the embodiment of the present invention, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE) and polyvinylidene fluoride (PVDF); a polyamide-based resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components. In addition, the filter can be appropriately selected according to hydrophilicity or hydrophobicity of the composition.

### <Film>

The film according to the embodiment of the present invention is a film formed of the above-described composition according to the embodiment of the present invention.

The refractive index of the film according to the embodiment of the present invention with light having a wavelength of 633 nm is preferably 1.4 or less, more preferably 1.35 or less, still more preferably 1.3 or less, and even more preferably 1.27 or less. The above-described value of the refractive index is a value at a measurement temperature of 25° C.

It is preferable that the film according to the embodiment of the present invention has sufficient hardness. In addition, the Young's modulus of the film is preferably 2 or more, more preferably 3 or more, and particularly preferably 4 or more. The upper limit value is preferably 10 or less.

A thickness of the film according to the embodiment of the present invention can be appropriately selected depending on the application. For example, the thickness of the film is preferably 5 μm or less, more preferably 3 μm or less, and particularly preferably 1.5 μm or less. The lower limit value is not particularly limited, but is preferably 50 nm or more.

The film according to the embodiment of the present invention can be used as an optically functional layer in an optical sensor such as a solid-state imaging element, an image display device, or the like. Examples of the optically functional layer include an antireflection layer, a layer of low refractive index, and a waveguide. In addition, the film according to the embodiment of the present invention can be used as a partition wall or the like used for separating adjacent pixels in a case of forming pixels on an image area of an optical sensor such as a solid-state imaging element or an image display device. Examples of the pixel include a colored pixel, a transparent pixel, a pixel of a near-infrared transmitting filter layer, and a pixel of a near-infrared cut filter layer. Examples of the colored pixel include a red pixel, a blue pixel, a green pixel, a yellow pixel, a cyan pixel, and a magenta pixel.

### <Method for Manufacturing Film>

The film according to the embodiment of the present invention can be formed through a step of applying the composition according to the embodiment of the present invention onto a support. The method for manufacturing the film preferably further includes a step of forming a pattern. Examples of the pattern forming method include a pattern forming method by a photolithography method and a pattern forming method by an etching method.

The pattern formation by the photolithography method preferably includes a step of applying the composition according to the embodiment of the present invention onto a support to form a composition layer, a step of exposing the composition layer in a patterned manner, and a step of removing a non-exposed portion of the composition layer by development to form a pattern. A step of baking the composition layer (pre-baking step) and a step of baking the developed pattern (post-baking step) may be provided, as desired.

In the step of forming the composition layer, a composition layer is formed by applying the composition according to the embodiment of the present invention onto a support. The support is not particularly limited, and can be appropriately selected depending on applications. Examples thereof include a substrate, for example, a wafer formed of a material such as silicon, non-alkali glass, soda glass, PYREX (registered trademark) glass, or quartz glass. In addition, it is also preferable to use an InGaAs substrate or the like. In addition, a charge coupled device (CCD), a complementary metal-oxide semiconductor (CMOS), a transparent conductive film, or the like may be formed on the support. In addition, a black matrix constituting of a light shielding material such as tungsten may be formed on the support. In addition, a base layer may be provided on the support so as to improve adhesiveness to an upper layer, prevent the diffusion of materials, or planarize the surface of the substrate. In addition, a microlens can also be used as the support.

As a method of applying the composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. The application method using an ink jet method is not particularly limited, and examples thereof include a method (in particular, pp. 115 to 133) described in “Extension of Use of Ink Jet—Infinite Possibilities in Patent-” (published on February, 2005, S.B. Research Co., Ltd.) and methods described in JP2003-262716A, JP2003-185831A, JP2003-261827A, JP2012-126830A, and JP2006-169325A. In addition, with regard to the method of applying the composition, reference can be made to the description in WO2017/030174A and WO2017/018419A, the contents of which are incorporated herein by reference.

The composition layer formed on the support may be dried (pre-baked). In a case of producing a film by a low-temperature process, the pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the composition layer is exposed in a patterned manner (exposure step). For example, the composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

Next, the non-exposed portion of the composition layer is removed by development to form a pattern. The non-exposed portion of the composition layer can be removed by development using a developer. As a result, the composition layer of the non-exposed portion in the exposure step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkaline agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

The formation of a pattern by an etching method preferably includes a step of applying the composition according to the embodiment of the present invention onto a support to form a composition layer and then curing the entire composition layer to form a cured composition layer; a step of forming a photoresist layer on this cured composition layer; a step of exposing the photoresist layer in a patterned manner and then developing the photoresist layer to form a resist pattern; a step of etching the cured composition layer using this resist pattern as a mask; and a step of peeling and removing the resist pattern from the cured composition layer.

A resist used for forming the resist pattern is not particularly limited. For example, a resist including an alkali-soluble phenol resin and naphthoquinone diazide described in pp. 16 to 22 of “Polymer New Material One Point 3, Microfabrication and Resist, author: Saburo Nonogaki, Published by Kyoritsu Shuppan Co., Ltd. (First Edition, Nov. 15, 1987) can be used. In addition, a resist described in Examples and the like of JP2568883B, JP2761786B, JP2711590B, JP2987526B, JP3133881B, JP3501427B, JP3373072B, JP3361636B, or JP1994-054383A (JP-H06-054383A) can also be used. In addition, as the resist, a so-called chemically amplified resist can also be used. Examples of the chemically amplified resist include a resist described in p. 129 and later of “New Developments of Photo-functional Polymer Materials”, (May 31, 1996, first print, edited by Kunihiro Ichimura, published by CMC) (in particular, a resist including a polyhydroxystyrene resin in which a hydroxy group is protected by an acid-decomposable group that is described in about page 131 or an Environmentally Stable Chemical Amplification Positive (ESCAP) resist which is described in about page 131 is preferable). In addition, a resist described in, for example, Examples and the like of JP2008-268875A, JP2008-249890A, JP2009-244829A, JP2011-013581A, JP2011-232657A, JP2012-003070A, JP2012-003071A, JP3638068B, JP4006492B, JP4000407B, or JP4194249B can also be used.

A method of etching the cured composition layer may be a dry etching or a wet etching. A dry etching is preferable.

The dry etching of the cured composition layer is preferably performed by using a mixed gas of a fluorine-based gas and O₂ as an etching gas. The mixing ratio (fluorine-based gas/O₂) of the fluorine-based gas and O₂ is preferably 4/1 to 1/5, and more preferably 1/2 to 1/4 in terms of flow rate ratio. Examples of the fluorine-based gas include CF₄, C₂F₆, C₃F₈, C₂F₄, C₄F₈, C₄F₆, C₅F₈, and CHF₃, and C₄F₆, C₅F₈, C₄F₈, or CHF₃ is preferable, C₄F₆ or C₅F₈ is more preferable, and C₄F₆ is still more preferable. As the fluorine-based gas, one kind of gas can be selected from the above-described group, and two or more kinds thereof may be included in the mixed gas.

From the viewpoint of maintaining partial pressure control stability of the etching plasma and verticality of the specific etching shape, the above-described mixed gas may further be mixed with a rare gas such as helium (He), neon (Ne), argon (Ar), krypton (Kr), and xenon (Xe), in addition to the fluorine-based gas and O₂. As other gases which may be mixed, one kind or two or more kinds of gases can be selected from the above-described group. In a case where O₂ is set to be 1, the mixing ratio of the other gases which may be mixed is preferably more than 0 and 25 or less, preferably 10 or more and 20 or less, and particularly preferably 16 in terms of flow rate ratio.

The internal pressure of a chamber during the dry etching is preferably 0.5 to 6.0 Pa, and more preferably 1 to 5 Pa.

Examples of dry etching conditions include conditions described in paragraphs 0102 to 0108 of WO2015/190374A, and JP2016-014856A, the contents of which are incorporated herein by reference.

An optical sensor or the like can also be manufactured by applying the method for manufacturing the film according to the embodiment of the present invention.

### <Structural Body>

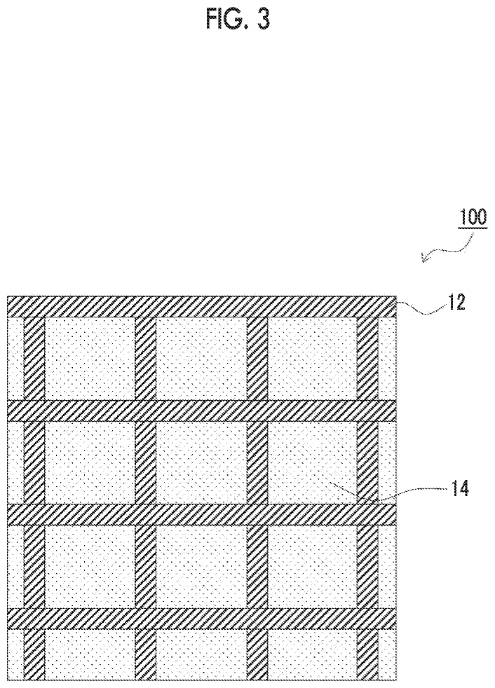

Next, the structural body according to an embodiment of the present invention will be described with reference to drawings. FIG. 2 is a side-sectional view showing an embodiment of the structural body according to the present invention, and FIG. 3 is a plan view of the structural body as viewed from directly above a support. As shown in FIGS. 2 and 3, a structural body 100 according to the embodiment of the present invention includes a support 11, a partition wall 12 provided on the support 11, and a pixel 14 provided on a region of the support 11 partitioned by the partition wall 12. Examples of the pixel include a colored pixel, a transparent pixel, a pixel of a near-infrared transmitting filter layer, and a pixel of a near-infrared cut filter layer. Examples of the colored pixel include a red pixel, a blue pixel, a green pixel, a yellow pixel, a cyan pixel, and a magenta pixel.

In the structural body according to the embodiment of the present invention, the type of the support 11 is not particularly limited. A substrate (silicon wafer, silicon carbide wafer, silicon nitride wafer, sapphire wafer, and glass wafer) used in various electronic devices such as a solid-state imaging element can be used. In addition, a substrate for a solid-state imaging element on which a photodiode is formed can also be used. In addition, as necessary, a base layer may be provided on these substrates so as to improve adhesiveness to an upper layer, prevent the diffusion of substances, or planarize the surface.

As shown in FIGS. 2 and 3, the partition wall 12 is formed on the support 11. In this embodiment, as shown in FIG. 3, the partition walls 12 are formed in a lattice form in a plan view seen from directly above the support 11. In this embodiment, the shape of the region partitioned by the partition wall 12 on the support 11 (hereinafter, also referred to as a shape of an opening portion of the partition wall) is a square shape, but the shape of the opening portion of the partition wall is not particularly limited, and may be, for example, a rectangular shape, a circular shape, an elliptical shape, a polygonal shape, or the like.

The partition wall 12 can be formed of the composition according to the embodiment of the present invention. Specifically, the partition wall 12 can be formed through a step of forming a composition layer using the composition according to the embodiment of the present invention, and a step of forming a pattern of the composition layer by a photolithography method or a dry etching method.

A width W1 of the partition wall 12 is preferably 20 to 500 nm. The lower limit is preferably 30 nm or more, more preferably 40 nm or more, and still more preferably 50 nm or more. The upper limit is preferably 300 nm or less, more preferably 200 nm or less, and still more preferably 100 nm or less.

In addition, a height H1 of the partition wall 12 is preferably 200 nm or more, more preferably 300 nm or more, and still more preferably 400 nm or more. The upper limit is preferably the thickness of the pixel 14×200% or less and more preferably the thickness of the pixel 14×150% or less, and it is still more preferable that the upper limit is substantially the same as the thickness of the pixel 14.

A height-to-width ratio (height/width) of the partition wall 12 is preferably 1 to 100, more preferably 5 to 50, and still more preferably 5 to 30.

The pixel 14 is formed in the region (opening portion of the partition wall) of the support 11 partitioned by the partition wall 12.

A width L1 of the pixel 14 can be appropriately selected depending on applications. For example, it is preferably 500 to 2,000 nm, more preferably 500 to 1,500 nm, and still more preferably 500 to 1,000 nm.

A height (thickness) H2 of the pixel 14 can be appropriately selected depending on applications. For example, it is preferably 300 to 1000 nm, more preferably 300 to 800 nm, and still more preferably 300 to 600 nm. In addition, the height H2 of the pixel 14 is preferably 50% to 150% of the height H1 of the partition wall 12, more preferably 70% to 130% of the height H1 of the partition wall 12, and still more preferably 90% to 110% of the height H1 of the partition wall 12.

In the structural body according to the embodiment of the present invention, it is also preferable that a protective layer is provided on the surface of the partition wall. By providing the protective layer on the surface of the partition wall 12, adhesiveness between the partition wall 12 and the pixels 14 can be improved. As a material of the protective layer, various inorganic materials and organic materials can be used. Examples of the organic material include acrylic resin, polystyrene resin, polyimide resin, and organic spin on glass (SOG) resin. In addition, the protective layer can also be formed of a composition containing a compound having an ethylenically unsaturated bond-containing group.

The structural body according to the embodiment of the present invention can be preferably used for an optical filter, an optical sensor, an image display device, and the like.

### <Optical Filter>

The optical filter according to the embodiment of the present invention has the above-described film according to the embodiment of the present invention. Examples of the optical filter having the film according to the embodiment of the present invention include an optical filter having a structure in which each pixel is embedded in a region partitioned by a partition wall formed of the film according to the embodiment of the present invention. Examples of the pixel include a colored pixel, a transparent pixel, a pixel of a near-infrared transmitting filter layer, and a pixel of a near-infrared cut filter layer.

A width of the pixel included in the optical filter is preferably 0.4 to 10.0 μm. The lower limit is preferably 0.4 μm or more, more preferably 0.5 μm or more, and still more preferably 0.6 μm or more. The upper limit is preferably 5.0 μm or less, more preferably 2.0 μm or less, still more preferably 1.0 μm or less, and even more preferably 0.8 μm or less. In addition, a Young's modulus of the pixel is preferably 0.5 to 20 GPa and more preferably 2.5 to 15 GPa.

Each pixel included in the optical filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured using an ultra-high resistance meter 5410 (manufactured by Advantest Corporation).

A protective layer may be provided on a surface of the pixel in the optical filter. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and more preferably 0.1 to 5 μm. Examples of a method of forming the protective layer include a method of applying and forming a composition for forming a protective layer, a chemical vapor deposition method, and a method of attaching a molded resin with an adhesive material. The protective layer may be formed of the composition according to the embodiment of the present invention. In addition, as the protective layer, protective layers described in paragraphs 0073 to 0092 of JP2017-151176A can also be used.

### <Optical Sensor>

The optical sensor according to the embodiment of the present invention includes the above-described film according to the embodiment of the present invention. Examples of the optical sensor include a solid-state imaging element. The configuration of the solid-state imaging element is not particularly limited as long as it functions as a solid-state imaging element.

### <Image Display Device>

The image display device according to the embodiment of the present invention includes the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published on 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published on 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. Materials, used amounts, proportions, treatment details, treatment procedures, and the like shown in the following examples can be appropriately changed within a range not departing from the scope of the present invention. Therefore, the scope of the present invention is not limited to the specific examples described below.

### <Production of Composition>

Raw materials described in the following tables were mixed and filtered using a DFA4201NIEY (0.45 μm nylon filter) manufactured by Nihon Pall Corporation to produce a composition. A numerical value of the blending amount of the surfactant in the tables below is a numerical value expressed in terms of solid contents. In addition, the cyclic siloxane compound was adjusted so that the content thereof in the composition was as shown in the tables below. In addition, in the tables below, the value of the proportion of the cyclic siloxane compound to 100 parts by mass of the silicone-based surfactant is shown together in the column of “Proportion of cyclic siloxane compound”.

TABLE 1

| | Dispersion liquid | | Surfactant | | Solvent | | Cyclic siloxane | | |
|---|---|---|---|---|---|---|---|---|---|
| | | Blending | | Blending | | Blending | compound | | Proportion of |
| | | amount | | amount | | amount | | Content | cyclic siloxane |
| | | (part by | | (part by | | (part by | | (ppm by | compound |
| | Type | mass) | Type | mass) | Type | mass) | Type | mass) | (part by mass) |
| Example 1-1 | Silica | 44.8 | W-1 | 0.0083 | S-1 | 43 | Sil-1 | 0.25 | 2.3 |
| | particle | | | | S-2 | 8 | Sil-2 | 0.83 | |
| | solution 1 | | | | S-3 | 2 | Sil-3 | 0.83 | |
| | | | | | S-4 | 1 | | | |
| | | | | | S-5 | 1 | | | |
| Example 1-2 | Silica | 44.8 | W-2 | 0.0083 | S-1 | 43 | Sil-1 | 0.83 | 1 |
| | particle | | | | S-2 | 8 | | | |
| | solution 1 | | | | S-3 | 2 | | | |
| | | | | | S-4 | 1 | | | |
| | | | | | S-5 | 1 | | | |
| Example 1-3 | Silica | 44.8 | W-3 | 0.0083 | S-1 | 43 | Sil-1 | 0.83 | 1 |
| | particle | | | | S-2 | 8 | | | |
| | solution 1 | | | | S-3 | 2 | | | |
| | | | | | S-4 | 1 | | | |
| | | | | | S-5 | 1 | | | |
| Example 1-4 | Silica | 44.8 | W-4 | 0.0083 | S-1 | 43 | Sil-3 | 0.25 | 0.3 |
| | particle | | | | S-2 | 8 | | | |
| | solution 1 | | | | S-3 | 2 | | | |
| | | | | | S-4 | 1 | | | |
| | | | | | S-5 | 1 | | | |
| Example 1-5 | Silica | 44.8 | W-5 | 0.0083 | S-1 | 43 | Sil-1 | 0.83 | 5 |
| | particle | | | | S-2 | 8 | Sil-2 | 2.49 | |
| | solution 1 | | | | S-3 | 2 | Sil-3 | 0.83 | |
| | | | | | S-4 | 1 | | | |
| | | | | | S-5 | 1 | | | |
| Example 1-6 | Silica | 44.8 | W-6 | 0.0083 | S-1 | 43 | Sil-1 | 0.83 | 1 |
| | particle | | | | S-2 | 8 | | | |
| | solution 1 | | | | S-3 | 2 | | | |
| | | | | | S-4 | 1 | | | |
| | | | | | S-5 | 1 | | | |
| Comparative | Silica | 44.8 | CW-1 | 0.0083 | S-1 | 43 | — | — | — |
| Example 1-1 | particle | | | | S-2 | 8 | | | |
| | solution 1 | | | | S-3 | 2 | | | |
| | | | | | S-4 | 1 | | | |
| | | | | | S-5 | 1 | | | |
| Comparative | Silica | 44.8 | W-6 | 0.0083 | S-1 | 43 | Sil-1 | 12.45 | 15 |
| Example 1-2 | particle | | | | S-2 | 8 | | | |
| | solution 1 | | | | S-3 | 2 | | | |
| | | | | | S-4 | 1 | | | |
| | | | | | S-5 | 1 | | | |

Among the raw materials listed in the above tables, details of the raw materials shown by abbreviations are as follows.

### [Dispersion Liquid]

Silica particle solution 1: silica particle solution which was prepared by 3.0 g of trimethylmethoxysilane as a hydrophobizing treatment agent was added to 100.0 g of propylene glycol monomethyl ether solution (silica particle concentration: 20% by mass) of silica particles (beaded silica) in which a plurality of spherical silicas having an average particle diameter of 15 nm were linked in a beaded shape by metal oxide-containing silica (linking material), and the mixture was reacted at 20° C. for 6 hours. As the average particle diameter of the spherical silica in the silica particle solution 1, the number average of circle-equivalent diameters in a projection image of the spherical portions of 50 spherical silicas measured by a transmission electron microscope (TEM) was calculated and obtained. In addition, in the silica particle solution 1, by a method of TEM observation, it was investigated whether or not the silica particle solution included silica particles having a shape in which a plurality of spherical silicas were connected in a beaded shape.

### [Surfactant]

W-1: compound having the following structure (hydroxyl number: 120 mgKOH/g, silicone-based surfactant)

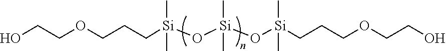

W-2: FZ-2122 (manufactured by Dow·TORAY, silicone-based surfactant)

W-3: SH 8400 FLUID (manufactured by Dow·TORAY, silicone-based surfactant)

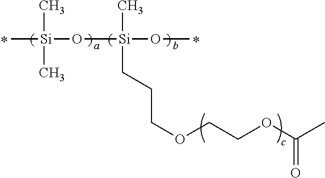

W-4: compound having the following structure (hydroxyl number: 62 mgKOH/g, silicone-based surfactant)

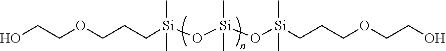

W-5: compound having the following structure (hydroxyl number: 35 mgKOH/g, silicone-based surfactant)

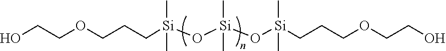

W-6: BYK-330 (manufactured by BYK Chemie, silicone-based surfactant)

CW-1: FTERGENT 710FM (manufactured by NEOS COMPANY LIMITED, fluorine-based surfactant)

### [Cyclic Siloxane Compound]

Sil-1: octamethylcyclotetrasiloxane
Sil-2: decamethylcyclopentasiloxane
Sil-3: dodecamethylcyclohexasiloxane

### [Solvent]

S-1: propylene glycol monomethyl ether acetate
S-2: 1,4-butanediol diacetate
S-3: methanol
S-4: ethanol
S-5: water

### <Evaluation of Defects>

Each composition was applied onto a silicon wafer having a diameter of 8 inch (20.32 cm) using a spin coater such that a film thickness after pre-baking was 0.6 μm, and a heating treatment (pre-baking) was performed for 120 seconds using a hot plate at 100° C. Next, the obtained film was inspected using a wafer defect evaluation device ComPLUS3 manufactured by Applied Materials, Inc., and the number of defects was obtained by counting defects having a size of 0.5 μm or more. In the 8-inch silicon wafer, a region located inside an outer peripheral portion by 5 mm or more was defined as an inspection range.
5: number of defects was 5 or less.
4: number of defects was more than 5 and 20 or less.
3: number of defects was more than 20 and 50 or less.
2: number of defects was more than 50 and 100 or less.
1: number of defects was more than 100.

TABLE 2

| | Evaluation of defects |
|---|---|
| Example 1-1 | 5 |
| Example 1-2 | 4 |
| Example 1-3 | 4 |
| Example 1-4 | 3 |
| Example 1-5 | 2 |
| Example 1-6 | 4 |
| Comparative Example 1-1 | 1 |
| Comparative Example 1-2 | 1 |

As shown in the above table, in all of Examples, it was possible to form a film with suppressed defects as compared with Comparative Examples. The same effects could be obtained even in a case where two or more kinds of surfactants were used.

### EXPLANATION OF REFERENCES

1: spherical silica
2: connection portion
11: support
12: partition wall
14: pixel
100: structural body

What is claimed is:

1. A composition comprising:
inorganic particles;
a cyclic siloxane compound; and
a silicone-based surfactant other than the cyclic siloxane compound,
wherein a content of the cyclic siloxane compound is 0.01 to 10 parts by mass with respect to 100 parts by mass of the silicone-based surfactant.

2. The composition according to claim 1,
wherein the cyclic siloxane compound is a compound represented by Formula (1), 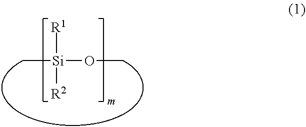
in Formula (1), R¹ and R² each independently represent a hydrogen atom or a substituent, and m represents an integer of 3 to 20.

3. The composition according to claim 1,
wherein the cyclic siloxane compound includes at least one selected from octamethylcyclotetrasiloxane, decamethylcyclopentasiloxane, or dodecamethylcyclohexasiloxane.

4. A composition comprising:
inorganic particles;
a cyclic siloxane compound; and
a silicone-based surfactant other than the cyclic siloxane compound,
wherein the cyclic siloxane compound is at least one selected from octamethylcyclotetrasiloxane, decamethylcyclopentasiloxane, or dodecamethylcyclohexasiloxane, and
a content of the cyclic siloxane compound is 0.01 to 10 parts by mass with respect to 100 parts by mass of the silicone-based surfactant.

5. The composition according to claim 1,
wherein the composition contains two or more kinds of the cyclic siloxane compounds.

6. The composition according to claim 1,
wherein a content of the silicone-based surfactant in the composition is 1 to 2,000 ppm by mass.

7. The composition according to claim 1,
wherein the inorganic particles include silica particles.

8. The composition according to claim 7,
wherein the silica particles include at least one selected from silica particles having a shape in which a plurality of spherical silicas are connected in a bead shape, silica particles having a shape in which a plurality of spherical silicas are connected in a planar shape, or silica particles having a hollow structure.

9. The composition according to claim 1,
wherein a content of the inorganic particles in a total solid content of the composition is 20% by mass or more.

10. A film formed of the composition according to claim 1.

11. An optical filter comprising:
the film according to claim 10.

12. An optical sensor comprising:
the film according to claim 10.

13. An image display device comprising:
the film according to claim 10.

14. A structural body comprising:
a support;
a partition wall formed of the composition according to claim 1, which is provided on the support; and
a pixel provided in a region partitioned by the partition wall.
